(19) United States
(12) Patent Application Publication
(10) Pub. No.: US 2010/0196828 A1
(43) Pub. Date: Aug. 5, 2010

(54) METHOD OF MANUFACTURING SEMICONDUCTOR DEVICE

(76) Inventor: Daisuke Kawamura, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/698,419

(22) Filed: Feb. 2, 2010

(30) Foreign Application Priority Data
Feb. 3, 2009 (JP) 2009-022661

(51) Int. Cl. G03F 7/20

(52) U.S. Cl. 430/311

(57) ABSTRACT

A film which becomes an outgassing generation source under reduced pressure or in a vacuum is formed on a substrate. A resist film an outgassing generation amount per unit area of which is smaller than the film under reduced pressure or in a vacuum is formed on the film in such a manner that the film is not exposed. The resist film is exposed by using pattern light of extreme ultraviolet (EUV) light. The resist film is developed. The substrate is processed by using the resist film and the film as a mask or by using the film as a mask.

### CROSS-REFERENCE TO RELATED APPLICATIONS

This application is based upon and claims the benefit of priority from prior Japanese Patent Application No. 2009-022661, filed Feb. 3, 2009, the entire contents of which are incorporated herein by reference.

### BACKGROUND OF THE INVENTION

1. Field of the Invention

The present invention relates to a method of manufacturing a semiconductor device using lithography based on extreme ultraviolet (EUV) light.

2. Description of the Related Art

In the EUV lithography, reduction in outgassing inside an exposure system is a problem mainly from a viewpoint of contamination in an optical system. In a resist process, attention is mainly paid to outgassing occurring from a resist film or the like caused by irradiation of EUV light. The outgassing is caused by a decomposition product generated by irradiating a photo-acid generator or dissolution inhibition unit of resin in the resist composite elements with EUV light or by residual solvent in the resist film. Further, decomposition or the like of resist composite elements which are not limited to the photo-acid generator and dissolution inhibition unit, the decomposition or the like being caused by irradiating the resist composite elements with EUV light, also causes outgassing.

In general, as for the reduction of outgassing due to a resist film in a photo-exposed area, measures are now advanced by improving the materials of the resist composite elements.

In Jpn. Pat. Appln. KOKAI Publication No. 2004-117619, and Jpn. Pat. Appln. KOKAI Publication No. 2004-348133, measures against outgassing of the photo-exposed area by something other than the materials of the resist composite elements are proposed. That is, an upper layer film used to prevent outgassing from occurring is provided above the resist film. However, in order to form the upper layer protection-film, costs of the film formation materials and film formation equipment are required. More specifically, when film formation is carried out by the spin-coating method, a baker unit configured to heat a substrate on which a coating film serving as an upper layer film is formed is required as the facilities in addition to a spin-coating unit. Further, at least a chemical solution of the upper layer film, and back-rinse solution are required. The mixing of the upper layer film and resist film may cause the deformation of resist patterns and the pattern defects. Furthermore, removal of the upper layer film is required after the pattern exposure process. By forming the upper layer film on the resist film, and removing the upper layer film, the possibility of a pattern defect of the resist pattern occurring is made stronger, and restrictions on the resist material and process development are tightened.

On the other hand, even at a photo-unexposed area, outgassing occurs. Occurrence of the outgassing at the photo-unexposed area is considered to be attributable to an adsorption of a volatile substance in the film on the substrate, and on the surface of the substrate or the like. That is, the volatile substance is exposed to reduced pressure or a vacuum to be volatilized, whereby the volatile substance outgasses. More specifically, volatilization of a residual solvent and moisture, volatilization of other substances in the coating film due to an azeotropic phenomenon of a residual solvent and other substances, or volatilization of an organic amine absorbed into a low-density substance such as a low-dielectric-constant film (low-k film) can be considered. For example, in an organic film of high carbon concentration used as a lower layer film of a coating-type hard mask, the residual solvent largely changes depending on the heating temperature of the coating film. Further, in the azeotropic phenomenon of the residual solvent, it is conceivable that a substance which has a high affinity for the residual solvent, has a large mutual interaction between itself and the residual solvent, and has a small mutual interaction between itself and the coating film is easily volatilized. Accordingly, there is the possibility of a low-molecular component having composition similar to a resin constituting the coating film, a cross-linking agent or thermal acid generator not reactive during the coating film formation process and heating process subsequent thereto, or their reaction products being volatilized under reduced pressure, and becoming a generation source of the outgassing.

Further, it is conceivable that in a lithography field a substrate known as a so-called poisoning substrate becomes a generation source of the outgassing. In a substrate in which an interlayer insulating film constituted of a low-k film, and having an opening part is formed, the interlayer insulating film absorbs an organic amine. It is known that as a result of this, a change in shape is caused to a resist pattern formed on/near the opening part of the interlayer insulating film.

Depending on the type of the upper layer film of Jpn. Pat. Appln. KOKAI Publication No. 2004-117619, and Jpn. Pat. Appln. KOKAI Publication No. 2004-348133, it is possible to expect an effect of reducing the outgassing of the photo-unexposed area by forming the upper layer film on a film which becomes a generation source of the outgassing. However, as described above, an increase in cost due to the chemical solutions and facilities is inevitable.

Further, in the conventional lithographic process, when a resist pattern is used as an etching mask, the laminated state of the resist film and the like at the wafer peripheral part and beveled part in the pattern exposure process has been specified on the basis of the restrictions on the etching process.

In Jpn. Pat. Appln. KOKAI Publication No. 2007-142181, and “K. Nakano et al, “Analysis and Improvement of Immersion Defectivity using Volume Production Immersion Lithography Tool”, 4th International Immersion Symposium, (2007), pp. 20-25”, a laminated structure of a film at the beveled part is specified. The laminated structure is specified in order to prevent a pattern defect and device contamination resulting from film exfoliation at the beveled part of the substrate due to friction between the immersion liquid and substrate from occurring. However, no measures against occurrence of outgassing under reduced pressure in the EUV lithography are taken.

### BRIEF SUMMARY OF THE INVENTION

According to a first aspect of the invention, there is provided a method of forming a semiconductor device comprising: forming a film which becomes an outgassing generation source under reduced pressure or in a vacuum on a substrate; forming a resist film an outgassing generation amount per unit area of which is smaller than the film under reduced pressure or in a vacuum on the film in such a manner that the film is not exposed; exposing the resist film by using pattern light of extreme ultraviolet (EUV) light; developing the resist film; and processing the substrate by using the resist film and the film as a mask or by using the film as a mask.

According to a second aspect of the invention, there is provided a method of forming a semiconductor device comprising: forming a substrate having the interlayer insulating film by forming, on a semiconductor substrate, an interlayer insulating film including an opening part which is an outgassing generation source under reduced pressure or in a vacuum; forming a resist film an outgassing generation amount per unit area of which is smaller than an outgassing generation amount per unit area of the opening part under reduced pressure or in a vacuum on the substrate in such a manner that the opening part is not exposed; exposing the resist film by using pattern light of EUV light; developing the resist film; and processing the substrate by using the resist film as a mask.

### BRIEF DESCRIPTION OF THE SEVERAL VIEWS OF THE DRAWING

FIG. 1 is a cross-sectional view showing a manufacturing process of a semiconductor device according to a first embodiment of the present invention.

FIG. 2 is a cross-sectional view showing a modification example of the manufacturing process of the semiconductor device according to the first embodiment of the present invention.

FIGS. 3 and 4 are cross-sectional views showing the manufacturing process of the semiconductor device according to the first embodiment of the present invention.

FIGS. 5 to 7 are cross-sectional views showing a manufacturing process of a semiconductor device according to a second embodiment of the present invention.

FIGS. 8 to 10 are cross-sectional views showing a manufacturing process of a semiconductor device according to a third embodiment of the present invention.

### DETAILED DESCRIPTION OF THE INVENTION

Embodiments of the present invention will be described below by referring to the accompanying drawings. In the drawings, the same parts are denoted by the same reference symbols.

### First Embodiment

A first embodiment is an example in which a hard mask of a two-layer structure is constituted of a high-carbon concentration organic film and a silicon-containing intermediate film which become a generation source of outgassing, and the hard mask is covered with a resist film. A detailed description will be given by paying attention mainly to the beveled part of a laminated film structure formed on a semiconductor substrate in the manufacturing process of a semiconductor device in this embodiment.

### [Configuration/Process]

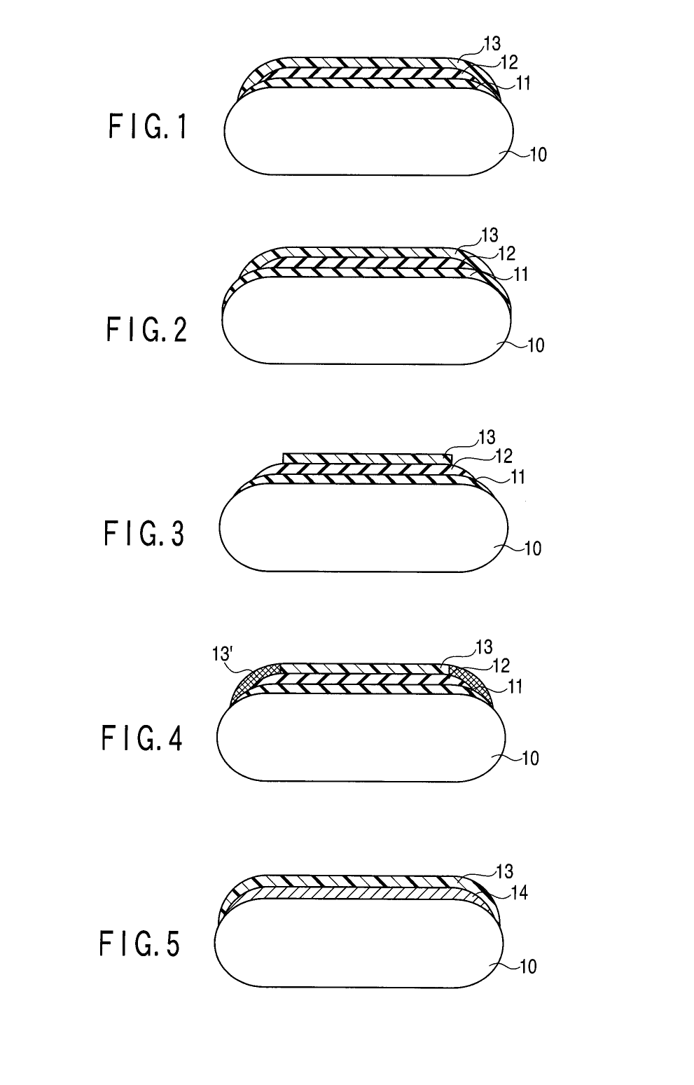

FIGS. 1 to 4 show cross-sectional views of the manufacturing process of the semiconductor device according to this embodiment. The manufacturing process of the semiconductor device according to this embodiment will be described below

First, as shown in FIG. 1, a high-carbon concentration organic film 11 is formed on a semiconductor substrate 10 (hereinafter referred to as a substrate 10) on which a film to be processed (not shown) is formed. The high-carbon concentration organic film 11 is formed by coating the substrate 10 with a coating film by, for example, a spin-coating method using a chemical solution, and thereafter heating the resultant coated film by using a baker. Here, in order that the high-carbon concentration organic film 11 may not be brought into contact with the inside of each of lithographic equipment, conveying equipment, and subsequent processing equipment in the process of the spin-coating method, the high-carbon concentration organic film 11 on the substrate 10 is subjected in advance to edge rinse and back rinse (which are hereinafter collectively referred to as a generic name of edge and back rinse (EBR)). As a result of this, a contact part of the high-carbon concentration organic film 11 at which the high-carbon concentration organic film 11 is brought into contact with each of the equipments is removed. Accordingly, it is possible to prevent the high-carbon concentration organic film 11 from becoming a dust source in each of the equipments, and causing a failure of each of the equipments. Further, as for the edge cutting position of the beveled part of the high-carbon concentration organic film 11 by the edge rinse, a permissible range is specified on the basis of the subsequent process such as etching process. It should be noted that it is desirable that the high-carbon concentration organic film 11 be a coating film with, for example, a carbon concentration of 60% by weight or more. Examples of the coating film with the carbon concentration of 60% by weight or more include organic substances with multiple aromatic rings structure and fullerene structure.

As another film formation method of the high-carbon concentration organic film 11, film deposition in a vapor phase such as the chemical vapor deposition (CVD) method or the like may be employed. When the high-carbon concentration organic film 11 is formed by the vapor phase growth, a predetermined guard ring may be provided on the wafer during the film deposition in place of carrying out the edge cutting. When the high-carbon concentration organic film 11 is formed by the vapor phase growth, a carbon film with a structure mainly of the amorphous carbon structure, fullerene structure or diamond structure may be employed in place of the multiple aromatic rings structure.

Then, a silicon-containing intermediate film 12 is formed on the high-carbon concentration organic film 11. The silicon-containing intermediate film 12 is formed by, for example, the spin-coating method. Here, it is desirable that the edge cutting position of the beveled part of the silicon-containing intermediate film 12 by the edge rinse be formed inside the edge cutting position of the beveled part of the high-carbon concentration organic film 11. This is because the high-carbon concentration organic film 11 is etched later by using an intermediate film pattern as etching mask. It should be noted that it is desirable that the silicon-containing intermediate film 12 be a coating film containing silicon and oxygen. Examples of the coating film containing silicon and oxygen include films having a siloxane structure and a film of polysilane structure or the like.

As another film deposition method of the silicon-containing intermediate film 12, film deposition in a vapor phase such as the CVD method or the like may be employed. When the silicon-containing intermediate film 12 is formed by the vapor phase growth, a predetermined guard ring may be provided on the wafer during the film deposition in place of carrying out the edge cutting.

In the manner described above, the hard mask with the two-layer structure, and constituted of the high-carbon concentration organic film 11 and silicon-containing intermediate film 12 is formed. The two-layered hard mask may generate outgassing by being exposed to reduced pressure or a vacuum.

Then, a resist film 13 is formed on the silicon-containing intermediate film 12. The resist film 13 is formed by, for example, the spin-coating method. Further, as for the resist film 13, in order to prevent outgassing from occurring, the photo-acid generator, dissolution inhibition unit of resin, solvent, and the like in the composite elements of the resist film 13 are improved. More specifically, a bulky material is used for the photo-acid generator in the composite elements of the resist film 13. Further, the dissolution inhibition unit of resin in the composite elements of the resist film 13 is bulked (see Pat. Document 1: “Proc. SPIE 5753, pp. 765-770, (2005)”, Pat. Document 2: “J. Photopolym. Sci. Technol., vol. 19 pp. 533-538, (2006)”, and Pat. Document 3: “Proc. SPIE 6923-41 (2008)”).

Here, when a generation amount of outgassing per unit area of the high-carbon concentration organic film 11 is larger than an outgassing generation amount per unit area of the resist film 13, the edge cutting position of the beveled part of the resist film 13 is formed outside the edge cutting position of the beveled part of each of the high-carbon concentration organic film 11 and silicon-containing intermediate film 12. Accordingly, as shown in FIG. 1, the edge cutting position of the resist film 13 is formed on the outermost side, further the high-carbon concentration organic film 11 and silicon-containing intermediate film 12 are completely covered with the resist film 13 at the central part and beveled part, and are not exposed. Further, regarding the edge cutting position of the resist film 13, a permissible range is specified in such a manner that the edge cutting position is not brought into contact with the conveying equipment or the like in the lithographic equipment during a period from the resist film formation process to the development process subsequent thereto.

It should be noted that, as shown in FIG. 2, when an outgassing generation amount per unit area of the high-carbon concentration organic film 11 is smaller than an outgassing generation amount per unit area of the resist film 13, and an outgassing generation amount per unit area of the silicon-containing intermediate film 12 is larger than that of the resist film 13, it is sufficient if the edge cutting position of the resist film 13 is formed outside at least the edge cutting position of the silicon-containing intermediate film 12. Accordingly, the edge cutting position of the resist film 13 may also be formed between the edge cutting position of the high-carbon concentration organic film 11 and edge cutting position of the silicon-containing intermediate film 12.

Further, it is also possible to form the edge cutting position of the silicon-containing intermediate film 12 outside the edge cutting position of the high-carbon concentration organic film 11. In this case, when the outgassing generation amount per unit area of the silicon-containing intermediate film 12 is equal to or larger than the outgassing generation amount per unit area of the resist film 13, it is recommendable to form the edge cutting position of the resist film 13 outside the edge cutting position of the silicon-containing intermediate film 12.

Then, the resist film 13 is subjected to a pattern exposure process using EUV light. As a result of this, a latent image is formed on the resist film 13. The pattern exposure process using EUV light is carried out in a vacuum. As a result of this, it is possible to prevent the EUV light from being absorbed into the atmosphere. As described above, the outgassing occurs during the steps of conveyance, measurement, and exposure in a vacuum in the pattern exposure process.

Then, the resist film 13 that has been subjected to the pattern exposure process using EUV light is further subjected to a post-exposure bake (PEB) process as the need arises. In general, when the resist film 13 is a chemically-amplified resist, the PEB process is carried out.

Then, the resist film 13 on which the latent image is formed is subjected to a development process. As a result of this, a resist pattern is formed on the resist film 13. In the development process, a developing solution normally used in the current resist process is, for example, an aqueous solution of TMAH with a concentration of 2.38%. However, the developing solution is not limited to this, and may be an aqueous solution of TMAH with a concentration less than the above. Further, a surfactant is added to the developing solution in accordance with the material or the like of the resist film 13 in some cases. Further, the developing solution is not limited to the TMAH aqueous solution depending on the type of the material of the resist film 13, and may be other chemical solutions. Examples of the other chemical solution include an organic alkaline solution such as tetra-butylammonium hydroxide (TBAH) or an alkaline solution of KOH and the like. Even in this case, it is possible to form a resist pattern on the resist film 13. When the resist film 13 is a PMMA resist or the like, the developing solution may also be an organic solvent.

Then, the resist film 13 that has been subjected to the development process is further subjected to a rinse process. As a result of this, a dissolved part of the resist film 13 at the photo-exposed area is removed. When a TMAH aqueous solution is used as the developing solution, the rinse process is carried out by using pure water or a surfactant aqueous solution. Further, when an organic solvent is used as the developing solution, the rinse process is carried out by using, in place of pure water, an organic solvent such as isopropyl alcohol or the like.

In the manufacturing process of the semiconductor device of this embodiment, the high-carbon concentration organic film 11, silicon-containing intermediate film 12, and resist film 13 are sequentially stacked on the substrate 10. As shown in FIG. 3, in the case of such a laminated structure, it is desirable, on the basis of a demand from the etching process to be subsequently carried out, that the edge cutting position of the resist film 13 obtained after the above rinse process has been carried out be inside the edge cutting position of the silicon-containing intermediate film 12.

Accordingly, as shown in FIG. 4, the beveled part of the resist film 13 is subjected to a wafer edge exposure process. As a result of this, the beveled part of the resist film 13 is exposed to the light (hereinafter referred to as a wafer edge exposure resist film 13′). At this time, in order that the wafer edge exposure resist film 13′ can be dissolved to the developer solution and removed in the PEB process and development process of the above process, the resist film 13 is exposed to light of a wavelength at which the resist film 13 is sensitively exposed during the above wafer edge exposure process. Accordingly, depending on the resist film 13, light of a wavelength emitted from a mercury lamp or light obtained through an appropriate wavelength filter selected in accordance with the need is used.

As described above, the wafer edge exposure resist film 13′ is removed in the development process. Accordingly, it is possible to obtain a desired edge cutting position of the resist film 13. Further, when the side surface of the wafer is not brought into contact with the inside of the lithographic equipment during the period from the resist film formation process to the development process, an end of the resist film 13 at the wafer beveled part may be positioned up to the side surface of the substrate 10. In this case, it is indispensable, during the wafer edge exposure process, to expose the resist film 13 on the side surface of the substrate 10 to the light, and during the development process, to remove the wafer edge exposure resist film 13′ on the side surface of the substrate 10.

The wafer edge exposure process is carried out during the period from the above-mentioned resist film formation process to the development process. Alternatively, when the PEB process becomes necessary, the wafer edge exposure process is carried out during the period from the resist film formation process to the PEB process. That is, the wafer edge exposure process is carried out either before the pattern exposure process or after the pattern exposure process. Regarding the fact that the wafer edge exposure process is carried out either before the pattern exposure process or after the pattern exposure process as described above, there are the following two ways of thinking. On the one hand, dimensional control configured to shorten and control the processing time from the pattern exposure process to the PEB process or from the pattern exposure process to the development process is emphasized. In this case, the wafer edge exposure process is carried out before the pattern exposure process. On the other hand, it is feared that outgassing would occur in the wafer edge exposure resist film 13′. In this case, the wafer edge exposure process is carried out after the pattern exposure process. Accordingly, the order of the wafer edge exposure process and pattern exposure process is appropriately determined from the viewpoint of the dimensional control or the outgassing amount.

Then, the silicon-containing intermediate film 12 is processed by using the resist pattern formed in the development process and rinse process as an etching mask, and an intermediate film pattern is formed. Thereafter, the remaining resist pattern is removed as the need arises.

Then, the high-carbon concentration organic film 11 is etched by using the intermediate film pattern as an etching mask. As a result of this, an organic film pattern is formed. Thereafter, the remaining resist pattern and intermediate film pattern are removed as the need arises.

Then, a film to be processed during the lithographic process on the substrate 10 is processed by using the organic film pattern as an etching mask. As a result of this, a desired pattern of the film to be processed is formed. Thereafter, etching masks of the remaining resist pattern, intermediate film pattern, and organic film pattern are removed, and the next manufacturing process of the semiconductor device is carried out.

It should be noted that in the manufacturing process of the semiconductor device in this embodiment, the case where the outgassing generation source is the high-carbon concentration organic film 11, and the case where the outgassing generation source is the high-carbon concentration organic film 11 and silicon-containing intermediate film 12 have been described. However, the above case is not limited to the case where the outgassing generation source is the two-layer hard mask constituted of the high-carbon concentration organic film 11 and silicon-containing intermediate film 12. That is, even in the case where the outgassing generation source is another hard mask, the same laminated structure can be applied to the edge cutting position of the beveled part of the hard mask and resist film 13. Further, the above case is not limited to the case where the outgassing generation source is the hard mask. That is, the above case may be a case where the outgassing generation source is a film under the resist film 13 to be used for the purpose other than the hard mask.

Furthermore, when the degree of the influence of the type of the outgas generated from the outgassing generation source on the EUV exposure system is abnormally higher than that of the type of the outgas generated from the resist film 13, it is desirable that the resist film 13 be formed on the outgassing generation source. That is, in the above case, even when the outgassing generation amount per unit area of the outgassing generation source is smaller than that of the resist film 13, it is desirable that the resist film 13 be formed in such a manner that the outgassing generation source is not exposed under reduced pressure during the EUV lithography or in a vacuum.

### [Advantage]

According to the first embodiment described above, in the EUV lithographic process, a resist film 13 to which measures against the outgassing are given is formed on a two-layer hard mask constituted of a high-carbon concentration organic film 11 and silicon-containing intermediate film 12 which become the generation source of the outgassing. That is, when the outgassing generation amount per unit area of the high-carbon concentration organic film 11 and silicon-containing intermediate film 12 is larger than that of the resist film 13 under the reduced pressure or in a vacuum during the EUV lithography, the high-carbon concentration organic film 11 and silicon-containing intermediate film 12 are completely covered with the resist film 13 at the central part and beveled part, and are not exposed. As a result of this, the high-carbon concentration organic film 11 and silicon-containing intermediate film 12 which become the outgassing generation source are not exposed under reduced pressure or in a vacuum. As a result of this, it is possible to prevent the outgassing from occurring at the photo-unexposed area. Accordingly, the outgassing generation amount is reduced, and contamination in the EUV exposure system due to the outgassing is also reduced. Further, it becomes possible to reduce the frequency of equipment maintenance services such as cleaning of the optical system, improve the equipment utilization rate, and reduce the manufacturing cost.

Further, in this embodiment, the resist film 13 to which measures against the outgassing are given is formed at the uppermost part. As a result of this, the process of forming the protective film or the like in order to prevent the outgassing from occurring is made unnecessary unlike in the case of Jpn. Pat. Appln. KOKAI Publication No. 2004-117619, and Jpn. Pat. Appln. KOKAI Publication No. 2004-348133. Accordingly, it becomes possible to save the costs of the film formation material and film formation equipment for the protective film or the like.

Here, the outgassing generation mechanism in the photo-unexposed area is not a little based on the diffusion phenomenon of the volatile substance in the film. Therefore, it is possible in some cases to reduce the residual solvent by increasing the length of the time for the high-temperature heating process, vacuum process or heating process to which the films and substrate 10 that become the outgassing generation source are subjected. However, in the high-carbon concentration organic film 11, deterioration in the quality of the film composition occurs due to oxidation or the like resulting from high-temperature heating. As a result of this, in the high-carbon concentration organic film 11, the function thereof as the etching hard mask deteriorates in some cases. On the other hand, the increase in the processing time causes lowering of productivity concomitant with the lowering of the processing efficiency. Thus, it is necessary to increase the number of processing equipments and units in order to maintain the productivity, and hence the cost is increased. As described above, although it is possible to suppress the outgassing generation by changing the processing conditions, it is often difficult to make the maintenance of the original capability of the film which becomes the outgassing generation source, and maintenance of the productivity compatible with each other.

However, in this embodiment, on the film which becomes the outgassing generation source, a resist film 13 is formed to cover the film. As a result of this, it is possible to suppress the outgassing generation without changing the processing conditions in the manufacturing process. Accordingly, it becomes possible to make the maintenance of the capability of the film which becomes the outgassing generation source, and maintenance of the productivity compatible with each other.

### Second Embodiment

In the first embodiment, the high-carbon concentration organic film, and silicon-containing intermediate film which become the outgassing generation source constitute the two-layer hard mask, and the hard mask is covered with the resist film. Conversely, a second embodiment is an example in which an organic conductive film which becomes an outgassing generation source is formed, and the organic conductive film is covered with a resist film. It should be noted that a description of parts of the second embodiment similar to those of the above first embodiment will be omitted, and parts different from the first embodiment will be described below in detail.

### [Configuration/Process]

FIGS. 5 to 7 show cross-sectional views of a manufacturing process of a semiconductor device according to this embodiment. The manufacturing process of the semiconductor device according to this embodiment will be described below.

First, as shown in FIG. 5, an organic film having conductivity (hereinafter referred to as an organic conductive film 14) is formed on a semiconductor substrate 10 (hereinafter referred to as a substrate 10) on which a film to be processed (not shown) is formed. The organic conductive film 14 is formed by coating the substrate 10 with a coating film by, for example, a spin-coating method using a chemical solution, and thereafter heating the resultant by using a baker. Here, in order that the substrate 10 may not be brought into contact with the inside of each of lithographic equipment, conveying equipment, and subsequent processing equipment in the process of the spin-coating method, the substrate 10 is subjected in advance to EBR. As a result of this, an edge cutting position of a beveled part of the organic conductive film 14 is formed inside the side surface of the substrate 10. The organic conductive film 14 is formed between the substrate 10 and a resist film 13 to be formed later, whereby it is possible to reduce an influence caused by a difference in material type between the substrate 10 and the resist film 13. It should be noted that examples of the organic conductive film 14 include polyacetylene derivatives and the like. However, examples of the organic conductive film 14 is not limited to this and may include resins of an acrylic structure, an ester structure or a novolac structure which have been added a cross linker. The organic conductive film 14 may generates outgassing by being exposed to reduced pressure or a vacuum.

Then, a resist film 13 is formed on the organic conductive film 14. The resist film 13 is formed by, for example, a spin-coating method. Here, when an outgassing generation amount per unit area of the organic conductive film 14 is larger than an outgassing generation amount per unit area of the resist film 13, the edge cutting position of the beveled part of the resist film 13 is formed outside the edge cutting position of the beveled part of the organic conductive film 14. Accordingly, the organic conductive film 14 is completely covered with the resist film 13 at the central part and beveled part, and is not exposed.

Then, the resist film 13 is subjected to a pattern exposure process using EUV light, and a latent image is formed thereon. The pattern exposure process using EUV light is carried out in a vacuum.

Then, the resist film 13 that has been subjected to the pattern exposure process using EUV light is further subjected to a PEB process as the need arises.

Then, the resist film 13 on which the latent image is formed is subjected to a development process, and a resist pattern is formed thereon.

Then, the resist film 13 that has been subjected to the development process is further subjected to a rinse process, and a dissolved part of the resist film 13 at the photo-exposed area is removed.

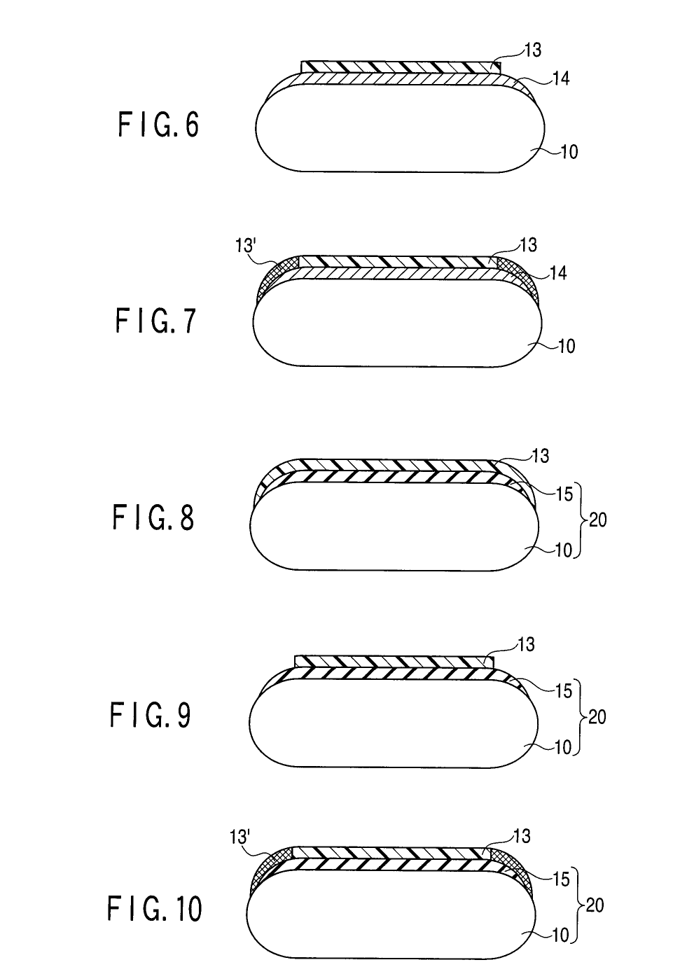

In the manufacturing process of the semiconductor device of this embodiment, the organic conductive film 14, and resist film 13 are sequentially stacked on the substrate 10. As shown in FIG. 6, in the case of such a laminated structure, it is desirable, on the basis of a demand from the etching process to be subsequently carried out, that the edge cutting position of the resist film 13 obtained after the above rinse process has been carried out be inside the edge cutting position of the organic conductive film 14.

Accordingly, as shown in FIG. 7, the beveled part of the resist film 13 is subjected to a wafer edge exposure process, and the beveled part of the resist film 13 is exposed to the light (hereinafter referred to as a wafer edge exposure resist film 13′). At this time, in order that the wafer edge exposure resist film 13′ can be melted and removed in the PEB process and development process of the above process, the resist film 13 is exposed to light of a wavelength at which the resist film 13 is sensitively exposed during the above wafer edge exposure process.

The wafer edge exposure process is carried out either before the pattern exposure process or after the pattern exposure process. Whether the wafer edge exposure process is carried out before the pattern exposure process or after the pattern exposure process is appropriately determined from the viewpoint of dimensional control or the outgassing amount.

Then, the organic conductive film 14 is processed by using the resist pattern formed in the development process and rinse process as a processing mask. As a result of this, a pattern constituted of the organic conductive film 14, and resist film 13 in the order from the lower layer is formed.

In general, the etching selectivity of the resist film 13 to the organic conductive film 14 is close to 1. Accordingly, when the organic conductive film 14 is processed, the thickness of the resist film 13 is reduced (processed) by an amount equivalent to the processed thickness of the organic conductive film 14. Furthermore, in the resist film 13, the processing proceeds in the lateral direction (dimension direction) depending on the degree of processing anisotropy. As a result of this, side etching by which the shape is changed from the original resist pattern occurs. The side etching has dependence on the pattern density, and type, and hence the shape fidelity deteriorates in some cases. Accordingly, it is desirable that the organic conductive film 14 be formed as thin as possible within a range in which the object of reducing an influence caused by a difference in material type between the substrate 10 and resist film 13 is achieved. For example, it is desirable that the thickness of the organic conductive film 14 be one third or less that of the resist film 13.

Then, by using the pattern constituted of the organic conductive film 14 and resist film 13 as a etching mask, the processing object film on the substrate 10 is etched. As a result of this, a desired pattern of the processing object film is formed. Thereafter, the remaining etching mask of the pattern constituted of the organic conductive film 14 and resist film 13 is removed, and the subsequently process of the semiconductor device is carried out.

It should be noted that in the manufacturing process of the semiconductor device in this embodiment, the case where the outgassing generation source is the organic conductive film 14 whose etching mask capability for the processing object film on the substrate is equivalent to that of the resist film 13 has been described. However, the outgassing generation source is not limited to this. When an organic film which is the outgassing generation source is used immediately below the resist, the role of the organic film is not limited to conductivity. The use of an organic film may have the merits in enhancing the adherence between the resist and the substrate, controlling the resists bottom profile, or reducing line edge roughness. That is, Even in the case where the outgassing generation source is not the organic film, but a one-layer coating type hard mask, the same laminated structure can be applied to the edge cutting position of the beveled part of the hard mask and resist film 13. At this time, the above case differs from this embodiment in the point that there is the possibility of the processing selection ratio of the resist film 13 to the one-layer coating type hard mask becoming larger than 1. Alternatively, the above case differs from this embodiment in the point that there is possibly a case where the resist film 13 is temporarily removed after forming the hard mask pattern depending on the characteristics of the one-layer hard mask. Further, in this embodiment, the above-mentioned one-layer hard mask or a two-layer hard mask may be formed under the organic conductive film 14. In this case, it is possible to reduce an influence caused by a difference in material type between the hard mask and resist film 13.

### [Advantage]

According to the second embodiment described above, under reduced pressure or in a vacuum in the EUV lithographic process, a resist film 13 to which measures against the outgassing are given is formed on the organic conductive film 14 which becomes the outgassing generation source. As a result of this, the organic conductive film 14 is completely covered with the resist film 13 at the central part and beveled part. Accordingly, like the first embodiment, it becomes possible to reduce the outgassing generation amount, and save the costs of the film formation material and film formation equipment for the protective film or the like used to suppress the outgassing.

### Third Embodiment

In the first and second embodiments, the outgassing generation source is a coating film formed on the substrate. Conversely, a third embodiment is an example in which the outgassing generation source is a substrate provided with an interlayer insulating film having an opening part, and the substrate is covered with a resist film. It should be noted that here, a description of the same parts as those of the first embodiment will be omitted, and parts different from the first embodiment will be described below in detail.

### [Configuration/Process]

FIGS. 8 to 10 show cross-sectional views of a manufacturing process of a semiconductor device according to this embodiment. The manufacturing process of the semiconductor device according to this embodiment will be described below.

First, as shown in FIG. 8, an interlayer insulating film 15 including a low-dielectric-constant film (low-k film) is formed on a wiring pattern (not shown) on a semiconductor substrate 10. This low-k film is, for example, a SiOC film, SiOF film, SiO₂—B₂O₃ film, porous silica film, organic siloxane film, and the like.

Then, an etching stopper film (not shown), upper wiring-layer formation film (not shown) or processing film (not shown) is formed on the low-k film. Thereafter, an opening part (not shown) is formed in the interlayer insulating film 15 by etching. Here, the interlayer insulating film 15 having the opening part occludes an organic amine into the opening part during an etching process for formation of the opening part or processing mask removal process for formation of the opening part. Accordingly, when the semiconductor substrate 10 on which the interlayer insulating film 15 having the opening part is formed is subjected to a vacuum process, the organic amine volatilizes. That is, the interlayer insulating film 15 having the opening part becomes an outgassing generation source. The semiconductor substrate 10 and interlayer insulating film 15 which has the opening part, and becomes the outgassing generation source will be called a substrate 20 hereinafter.

Then, a resist film 13 is formed on the substrate 20. Here, when an outgassing generation amount per unit area of the opening part of the interlayer insulating film 15 is larger than an outgassing generation amount per unit area of the resist film 13, the edge cutting position of the beveled part of the resist film 13 is formed outside the edge cutting position of the beveled part of the interlayer insulating film 15. Accordingly, the opening part of the interlayer insulating film 15 is completely covered with the resist film 13 at the central part and beveled part, and is not exposed.

Then, the resist film 13 is subjected to a pattern exposure process using EUV light, development process, and rinse process in the order mentioned. Further, after the pattern exposure process using EUV light, a PEB process is carried out as the need arises.

In the manufacturing process of the semiconductor device in this embodiment, the resist film 13 is formed on the substrate 20 provided with the interlayer insulating film 15 having the opening part. As shown in FIG. 9, in the case of such a laminated structure, it is desirable, on the basis of a demand from the etching process to be subsequently carried out, that the edge cutting position of the resist film 13 obtained after the above rinse process has been carried out be inside the edge cutting position of the interlayer insulating film 15.

Accordingly, as shown in FIG. 10, the beveled part of the resist film 13 is subjected to a wafer edge exposure process, and the beveled part of the resist film 13 is exposed to the light (hereinafter referred to as a wafer edge exposure resist film 13′). The wafer edge exposure process is carried out either before or after the pattern exposure process.

Then, by using a resist pattern formed by the development process and rinse process as an etching mask, the substrate 20 provided with the interlayer insulating film 15 having the opening part is processed. As a result of this, a desired substrate pattern is formed. Thereafter, the remaining etching mask of the resist pattern is removed, and the next manufacturing process of the semiconductor device is carried out.

It should be noted that a processing object film such as a silicon dioxide film, silicon nitride film or the like may be formed on the substrate 20. In this case, the processing object film and substrate 20 are processed by using the resist pattern as an etching mask.

### [Advantage]

According to the third embodiment described above, under reduced pressure or in a vacuum during the EUV lithographic process, a resist film 13 to which measures against the outgassing are given is formed on the substrate 20 provided with the interlayer insulating film 15 having the opening part which becomes the outgassing generation source. As a result of this, the opening part of the interlayer insulating film 15 is completely covered with the resist film 13 at the central part and beveled part. Accordingly, even when the outgassing generation source is a film other than a coating film, it becomes possible, like the first embodiment, to reduce the outgassing generation amount, and save the costs of the film formation material and film formation equipment for the protective film or the like used to suppress the outgassing.

Here, it is possible in some cases to reduce the amount of the absorbed organic amine or the like by changing the processing conditions of the film and substrate 20 which become the outgassing generation source. However, in the interlayer insulating film 15 including the low-k film, by changing the processing conditions, a change in the film density occurs, and the original function as the film deteriorates in some cases. Further, an increase in the processing time causes lowering of productivity concomitant with the lowering of the processing efficiency.

However, in this embodiment, a resist film 13 is formed on the film which becomes the outgassing generation source, whereby it becomes possible to make the maintenance of the capability of the film which becomes the outgassing generation source, and maintenance of the productivity compatible with each other.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of forming a semiconductor device comprising:
forming a film which becomes an outgassing generation source under reduced pressure or in a vacuum on a substrate;
forming a resist film an outgassing generation amount per unit area of which is smaller than the film under reduced pressure or in a vacuum on the film in such a manner that the film is not exposed;
exposing the resist film by using pattern light of extreme ultraviolet (EUV) light;
developing the resist film; and
processing the substrate by using the resist film and the film as a mask or by using the film as a mask.

2. The method according to claim 1, wherein the film comprises a laminated film including a first film which is an organic film formed on the substrate, and a second film formed on the first film, and containing silicon and oxygen.

3. The method according to claim 2, wherein the first film is a film with a carbon concentration of 60% by weight or more.

4. The method according to claim 2, wherein the first film contains multiple aromatic rings structure, and
the second film contains a siloxane structure or a polysilane structure.

5. The method according to claim 2, wherein an edge cutting position of the second film is formed inside an edge cutting position of the first film.

6. The method according to claim 1, wherein the film comprises an organic film provided with conductivity.

7. The method according to claim 6, wherein the organic film is a film of a polyacetylene derivative.

8. The method according to claim 6, wherein the thickness of the organic film is one third or less that of the resist film.

9. The method according to claim 1, further comprising:
performing heat treatment for the resist film after exposure of the resist film, and before development of the resist film.

10. The method according to claim 1, further comprising:
exposing an end part of the resist film before exposure of the resist film or after exposure thereof, and before development of the resist film,
wherein when the resist film is developed, the exposed end part of the resist film is also developed, and an edge cutting position of the resist film is formed inside an edge cutting position of the film.

11. The method according to claim 10, wherein the exposure of the end part of the resist film is performed by using light of a wavelength emitted from a mercury lamp.

12. A method of forming a semiconductor device comprising:
forming a substrate having the interlayer insulating film by forming, on a semiconductor substrate, an interlayer insulating film including an opening part which is an outgassing generation source under reduced pressure or in a vacuum;
forming a resist film an outgassing generation amount per unit area of which is smaller than an outgassing generation amount per unit area of the opening part under reduced pressure or in a vacuum on the substrate in such a manner that the opening part is not exposed;
exposing the resist film by using pattern light of EUV light;
developing the resist film; and
processing the substrate by using the resist film as a mask.

13. The method according to claim 12, wherein the interlayer insulating film is a low-dielectric-constant film.

14. The method according to claim 13, wherein the low-dielectric-constant film is one of an SiOC film, SiOF film, SiO₂—B₂O₃ film, porous silica film and organic siloxane film.

15. The method according to claim 12, further comprising:
performing heat treatment for the resist film after exposure of the resist film, and before development of the resist film.

16. The method according to claim 12, further comprising:
exposing an end part of the resist film before exposure of the resist film or after exposure thereof, and before development of the resist film,
wherein when the resist film is developed, the exposed end part of the resist film is also developed, and an edge cutting position of the resist film is formed inside an edge cutting position of the film.

17. The method according to claim 16, wherein the exposure of the end part of the resist film is performed by using light of a wavelength emitted from a mercury lamp.
